(19) United States
(12) Patent Application Publication
(10) Pub. No.: US 2026/0227247 A1
(43) Pub. Date: Aug. 6, 2026

(54) MEASURING DEVICE, INFORMATION PROCESSING SYSTEM, AND MEASURING METHOD

(71) Applicant: TOPOLOGIC INC., Tokyo (JP)

(72) Inventor: Arata TAKAHASHI, Tokyo (JP)

(21) Appl. No.: 19/153,091

(22) PCT Filed: Feb. 7, 2024
(86) PCT No.: PCT/JP2024/004206

§ 371 Date: Aug. 1, 2025

(30) Foreign Application Priority Data
Feb. 8, 2023 (JP) 2023-018004

(51) Int. Cl. G01K 7/18; G01K 3/14; G01K 17/00; G01R 19/10

(52) U.S. Cl. CPC G01K 7/18; G01K 3/14; G01K 17/00; G01R 19/10

(57) ABSTRACT

A measuring apparatus comprises a thermoelectric conversion circuit, a heat flow measuring unit, and a temperature measuring unit. The thermoelectric conversion circuit includes an element configured to generate an electromotive force by a temperature gradient generated through heat exchange with an object being measured. The heat flow measuring unit measures heat flow generated in the object being measured on the basis of an electrical signal generated in the thermoelectric conversion circuit by the electromotive force. The temperature measuring unit causes a second current to flow along a pathway through which a first current resulting from the electromotive force flows in at least a portion of the thermoelectric conversion circuit, measures electrical resistance of the portion, and measures temperature of the object being measured on the basis of the electrical resistance. The apparatus measures heat flow and temperature at the same location.

### CROSS REFERENCE TO RELATED APPLICATIONS

This application is a 371 U.S. National Phase of International Application No. PCT/JP2024/004206, filed on Feb. 7, 2024, which claims priority to Japanese Patent Application No. 2023-018004, filed on Feb. 8, 2023. The entire disclosures of the above applications are incorporated herein by reference.

### BACKGROUND

### Technical Field

The present invention relates to a measuring device (apparatus), an information processing system, and a measuring method.

### Related Art

Japanese Unexamined Patent Application Publication No. 2014-149158 (PTL 1) discloses a technology in which a heat flux sensor and a temperature sensor are provided at different points on a test battery, and the temperature of the test battery is controlled.

When a heat flux sensor and a temperature sensor are provided at different points, they do not measure the heat flux and the temperature at the same point. Accordingly, it is not possible to perform control or information processing based on the heat flux and temperature at the same point.

In view of the above circumstances, the present invention provides a device and the like configured to measure heat flux and temperature at the same point.

### SUMMARY

According to one aspect of the present invention, a measuring device is provided. The measuring device includes a thermoelectric conversion circuit, a heat flux measurement unit, and a temperature measurement unit. The thermoelectric conversion circuit includes an element configured to generate an electromotive force due to a temperature gradient caused by heat exchange with a measurement object. The heat flux measurement unit is configured to measure a heat flux occurring in the measurement object, based on an electrical signal generated in the thermoelectric conversion circuit by the electromotive force. The temperature measurement unit is configured to apply a second current along a path through which a first current flows due to the electromotive force in at least a portion of the thermoelectric conversion circuit, measure an electrical resistance of at least a portion of the thermoelectric conversion circuit, and measure a temperature of the measurement object based on the electrical resistance.

According to the configuration as such, a device and the like configured to measure heat flux and temperature at the same point can be provided.

### BRIEF DESCRIPTION OF THE DRAWINGS

FIG. 1 is a diagram illustrating a conventional measuring method.

FIGS. 2A and 2B include diagrams illustrating an example of a heat flux sensor.

FIG. 3 is a diagram schematically illustrating an example of the appearance of a measurement system 1.

FIG. 4 is a diagram illustrating an example of the detailed components of the measurement system 1.

FIG. 5 is an enlarged view of a thermoelectric conversion device 22.

FIG. 6 is a block diagram illustrating the hardware configuration of a user terminal 4.

FIGS. 7A and 7B include diagrams illustrating an example of measurement errors.

FIG. 8 is a diagram illustrating an example of a measuring method.

FIG. 9 is a diagram illustrating an example of a measuring method.

FIG. 10 is a diagram illustrating an example of a sensing current.

FIG. 11 is a diagram illustrating an example of a sensing current.

FIG. 12 is a diagram for describing a temperature being measured.

FIG. 13 is an activity diagram illustrating an example of the flow of information processing.

### DETAILED DESCRIPTION

Hereinafter, a preferred embodiment of the present disclosure will be described in detail with reference to the accompanying drawings. In this specification and the drawings, components having substantially the same functional configuration are denoted by the same reference numerals, and duplicate description thereof is omitted.

By the way, a program for implementing software described in the present embodiment may be provided on a non-transitory computer-readable recording medium, or it may be made available for download from an external server. Alternatively, it may be provided in a manner that allows the program to be run on an external computer, thereby implementing its functions on a client terminal (i.e., cloud computing).

In the present embodiment, the term “unit” may also include, for example, a combination of hardware resources implemented by a circuit in a broad sense, as well as the information processing performed by software that may be specifically implemented by such hardware resources. Additionally, various types of information are handled in the present embodiment, and such information may be represented by physical values such as signal values indicating voltage or current, by high and low signal levels in a binary bit set consisting of 0s and 1s, or by quantum superposition (i.e., quantum bits), and communication and computation may be executed by a circuit in a broad sense.

Furthermore, the term “circuit” in a broad sense refers to a circuit that is implemented by appropriately combining at least a circuit, circuitry, processor, and memory. That is, it includes application-specific integrated circuits (ASICs), programmable logic devices (such as simple programmable logic devices (SPLDs), complex programmable logic devices (CPLDs) and field-programmable gate arrays (FPGAs)), and other similar devices.

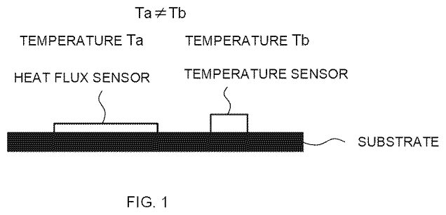

FIG. 1 is a diagram illustrating a conventional measuring method. As illustrated in FIG. 1, a conventional heat flux sensor, for example, is configured to detect the flow of heat, but is not capable of directly measuring temperature. Therefore, for example, temperature information can be obtained by providing a thermometer separately from the heat flux sensor. This makes it possible to measure the temperature deep inside. However, as described above, it is necessary to provide a separate thermometer. Additionally, if the positions of the heat flux sensor and the thermometer differ, a temperature Ta at the location of the heat flux sensor and a temperature Tb at the location of the thermometer may differ, which can result in a significant error.

Therefore, a device according to the present embodiment and a system using the device, as well as a method using the device or the system, measure the resistance of the heat flux sensor (In detail, an element) itself and estimate the temperature Ta of the heat flux sensor by using the correlation between the temperature and resistance of the heat flux sensor. This makes it possible to obtain temperature information from the heat flux sensor without having to provide a thermometer, thereby eliminating errors as mentioned above. As a result, the device can be miniaturized.

The present embodiment will now be described. The heat flux sensor (an example of a device) according to the present embodiment is preferably a thin-film heat flux sensor based on transverse thermoelectric effects, such as the anomalous Nernst effect or the spin Seebeck effect, from the viewpoint of responsiveness. An element (thermoelectric conversion element) of the heat flux sensor (i.e., thermoelectric conversion device) may be composed of a compound that exhibits the anomalous Nernst effect. The element may be composed of a topological ferromagnetic material or a topological antiferromagnetic material, which is called a Weyl semimetal, for example, or it may be composed of a ferrimagnetic material or a combination of these. The topological ferromagnetic material may be a metal having a Co₂MnX composition, such as Co₂MnGa (where X is any one of Si, Ge, Sn, Al, or Ga), or an alloy of a known topological ferromagnetic material such as a metal represented by the formula Fe₃X (where X is a typical element such as Al or Ga, or a transition element, and the composition may either be stoichiometric or off-stoichiometric). The topological antiferromagnetic material may be a known topological antiferromagnet such as Mn₃X (where X is one or more elements selected from Sn, Ge, Ga, Pt, Ir, and Rh, or a compound thereof). The compound forming the element may be, for example, an alloy containing a transition metal, and the alloy may be a compound having a crystal structure that includes a Kagome lattice plane composed of transition metals, and may exhibit the anomalous Nernst effect. The composition ratio of the alloy forming the topological ferromagnet or topological antiferromagnet is not necessarily limited to the above-mentioned stoichiometric composition ratios; as long as it has a partially stoichiometric structure (e.g., DO3-type crystal structure or B2-type crystal structure), the composition ratio is not particularly limited. The ferrimagnet is also not particularly limited, as long as it exhibits the anomalous Nernst effect. The structure of the element is not particularly limited, and a known structure may be used. Moreover, the element according to the present embodiment may be formed by sputtering, vapor deposition, MBE, plating, sintering, printing, bonding, or similar methods.

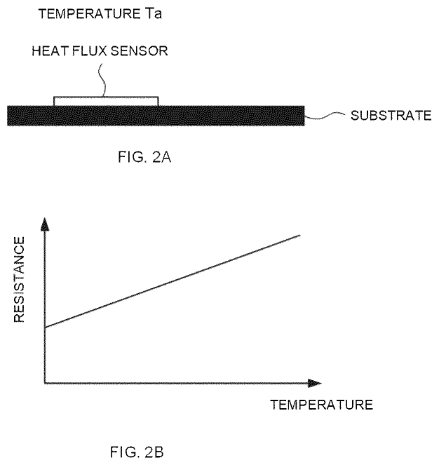

FIGS. 2A and 2B include diagrams illustrating an example of the heat flux sensor. As illustrated in FIGS. 2A and 2B, the heat flux sensor (an example of a device) according to the present embodiment is a heat flux sensor provided on a substrate. The heat flux sensor may be equipped with a processor such as a microcontroller or FPGA (not illustrated), or such a processor may be provided outside the heat flux sensor. The processor obtains information on the resistance of the heat flux sensor, which is measured using a known means. According to the inventors of the present invention, it has been revealed that the resistance of the heat flux sensor has a characteristic of a quasi-linear function with respect to temperature. Therefore, the temperature of the heat flux sensor can be estimated by measuring the resistance of the heat flux sensor. This allows the heat flux sensor according to the present embodiment to obtain not only the heat flux value but also the temperature of the heat flux sensor. Note that the temperature of the heat flux sensor as used herein refers to the internal temperature of the heat flux sensor. The temperature on the upper surface and/or lower surface of the heat flux sensor can be obtained by other means.

### <Measurement System 1>

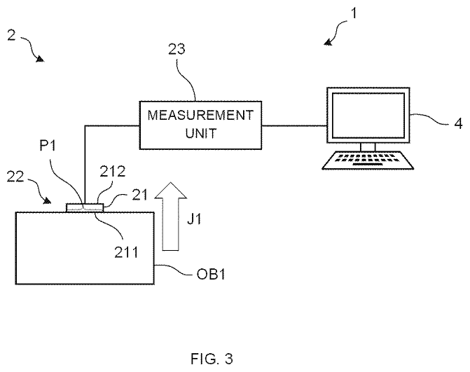

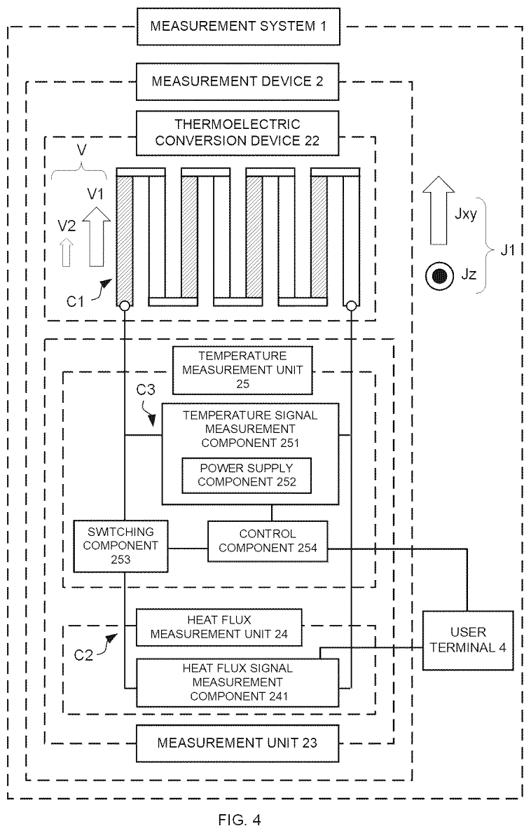

An example of a measuring device that measures the heat flux and temperature of a measurement object as described above, and a measurement system equipped with the measuring device will now be described with reference to FIGS. 3 and 4.

FIG. 3 is a diagram schematically illustrating an example of the appearance of a measurement system 1. FIG. 4 is a diagram illustrating an example of the detailed components of the measurement system 1. The measurement system 1 includes a measuring device 2 and a user terminal 4.

The measuring device 2 measures the heat flux and temperature at a measurement point P1 on a measurement object OB1. The user terminal 4 obtains the result of the measurement conducted by the measuring device 2 and performs information processing based on the obtained measurement result. The information processing performed by the user terminal 4 may be any type of information processing as long as it is based on the heat flux and temperature of the measurement object OB1 (e.g., a process of calculating the temperature deep inside).

### <Measuring Device 2>

The measuring device 2 includes a thermoelectric conversion device 22 and a measurement unit 23.

### <Thermoelectric Conversion Device 22>

The thermoelectric conversion device 22 is a device that converts heat flux into electrical power and is an example of the aforementioned heat flux sensor. The thermoelectric conversion device 22 is provided so as to be in close contact with the measurement point P1 on the measurement object OB1, and is configured to generate a temperature gradient J1 through heat exchange with the measurement object OB1. Heat exchange includes the inflow of heat from the measurement object OB1 into the thermoelectric conversion device 22 and the outflow of heat from the thermoelectric conversion device 22 into the measurement object OB1. The thermoelectric conversion device 22 is configured to output a thermoelectromotive force V based on the temperature gradient J1. Note that the measurement object OB1 may be any arbitrary object. The measurement object OB1 is not limited to solids and may also be any fluid, such as a liquid or gas, provided that the thermoelectric conversion device 22 can be attached thereto. The thermoelectric conversion device 22 has a substrate 21.

### <Substrate 21>

The substrate 21 is configured to exchange heat with the measurement point P1 on the measurement object OB1. This causes the inflow of heat from the measurement point P1 on the measurement object OB1 into the substrate 21 or the outflow of heat from the measurement point P1 on the measurement object OB1 into the substrate 21. The substrate 21, for example, comes into direct contact with the measurement object OB1 so that heat from the measurement object OB1 is exchanged directly, without passing through any other component. This helps reduce measurement errors in the temperature gradient J1, which will be discussed later. Note that the substrate 21 may also be in indirect contact with the measurement object OB1 with an intermediate material, such as a membrane, film, or coated material, interposed therebetween. This allows the thermoelectric conversion device 22 to be attachable to a wider variety of measurement objects OB1.

The substrate 21 of the present embodiment is a planar printed circuit board. Note that the specific form of the substrate 21 is not limited to this and may be any form. For example, it may be a substrate made of a semiconductor or insulator such as silicon or MgO, or it may even be the surface of the measurement object OB1 itself. Alternatively, the substrate 21 may be, for example, a metal plate, or it may be a printed circuit board or similar base with a metal coating or other surface treatment. The substrate 21 has two surfaces: a contact surface 211 and a front surface 212.

### <Contact Surface 211>

The contact surface 211 is configured to be able to come into contact with the measurement point P1 on the measurement object OB1. This causes heat from the measurement point P1 on the measurement object OB1 to be conducted to the substrate 21 via the contact surface 211. In the present embodiment, the contact surface 211 is a single continuous surface.

### <Front Surface 212>

The front surface 212 is the surface that becomes the front side when the contact surface 211 of the thermoelectric conversion device 22 is brought into close contact with the measurement point P1 on the measurement object OB1. That is, the front surface 212 is opposite to the contact surface 211 in the thickness direction of the substrate 21. In the present embodiment, the front surface 212 is a single continuous surface.

Note that the shape of the substrate 21 is arbitrary and is not limited to a flat shape; it may include curved surfaces or bent points. The substrate 21 may also be a deformable, so-called flexible substrate. This facilitates the measurement of the temperature gradient J1 of a measurement object OB1 that has a curved surface.

The temperature gradient J1 includes at least a vertical component Jz relative to the front surface 212. The vertical component Jz of the temperature gradient J1 is the component of the temperature gradient J1 that is perpendicular to the front surface 212. If the substrate 21 has a curved surface or similar shape, the direction perpendicular to the front surface 212 may be defined by the local normal direction of the curved surface. Accordingly, the direction perpendicular to the front surface 212 is not necessarily uniform across the entire area of the front surface 212.

In the present embodiment, the temperature gradient J1 may include an in-plane component Jxy. The in-plane component Jxy may be caused by variations in heat in the in-plane direction of the substrate 21 or variations in heat conduction. The in-plane component Jxy is the component of the temperature gradient J1 that is parallel to the front surface 212. If the substrate 21 has a curved surface or similar shape, the direction parallel to the front surface 212 may be defined by a direction perpendicular to the local normal direction of the curved surface. Accordingly, the direction parallel to the front surface 212 is not necessarily uniform across the entire area of the front surface 212.

Note that being “perpendicular” to a certain direction or plane is not limited to being perfectly perpendicular to that direction or plane, but may also include, for example, being perpendicular within an acceptable margin of error in terms of dimensions or the like. Similarly, being “parallel” to a certain direction or plane is not limited to being perfectly perpendicular to that direction or plane.

### <Thermoelectromotive Force V>

As illustrated in FIG. 4, the aforementioned thermoelectromotive force V may include a first electromotive force V1 and a second electromotive force V2. The first electromotive force V1 is a thermoelectromotive force generated by a first thermoelectric conversion effect based on the vertical component Jz of the temperature gradient J1 relative to the front surface 212. The first thermoelectric conversion effect has a manifestation mechanism different from that of the Seebeck effect, and is, for example, exhibited by the off-diagonal components of the thermoelectric tensor, such as the anomalous Nernst effect or the spin Seebeck effect.

The first electromotive force V1 is expressed, for example, by a quantity that depends on a physical variable corresponding to a magnetic field, among the off-diagonal components of the thermoelectric tensor of the thermoelectric conversion device 22. The first electromotive force V1 is antisymmetric with respect to the magnetic field, symmetric with respect to the in-plane component Jxy, and antisymmetric with respect to the vertical component Jz. The direction of the first electromotive force V1 is approximately perpendicular to the vertical component Jz.

The second electromotive force V2 is a thermoelectromotive force generated by a second thermoelectric effect based on the in-plane component Jxy of the temperature gradient J1 relative to the front surface 212. The second thermoelectric conversion effect has a manifestation mechanism different from that of the first thermoelectric conversion effect, and is exhibited by the diagonal components of the thermoelectric tensor, such as the Seebeck effect. The second electromotive force V2 is expressed, for example, by a quantity that depends on a physical variable corresponding to the temperature gradient J1, among the diagonal components of the thermoelectric tensor of the thermoelectric conversion device 22. The second electromotive force V2 is a quantity that becomes antisymmetric with respect to the temperature gradient. The direction of the second electromotive force V2 is approximately parallel to the direction of the in-plane component Jxy. When the in-plane component Jxy is parallel to the direction of the first electromotive force V1, the direction of the second electromotive force V2 is approximately parallel to the direction of the first electromotive force V1.

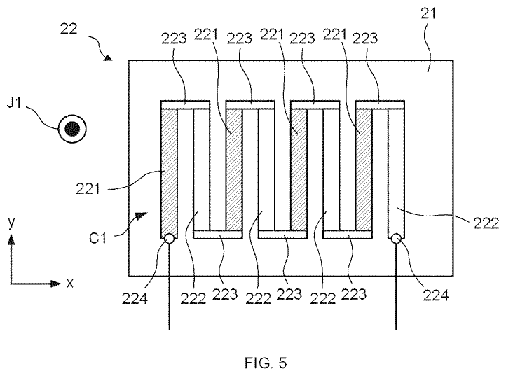

The thermoelectric conversion device 22 will now be described in detail with reference to FIG. 5.

FIG. 5 is an enlarged view of the thermoelectric conversion device 22. As illustrated in FIG. 5, the thermoelectric conversion device 22 has multiple thermoelectric conversion elements 221. The thermoelectric conversion device 22 further includes first conductor parts 222 as conductor parts, second conductor parts 223 as conductor parts, and at least a pair of measurement terminals 224.

The substrate 21 is provided so as to insulate the measurement object OB1 from the thermoelectric conversion elements 221. The configuration of the substrate 21 is arbitrary, provided that the measurement object OB1 is insulated from the thermoelectric conversion elements 221, the first conductor parts 222, the second conductor parts 223, and the measurement terminals 224, and that heat flows from the measurement object OB1 into the thermoelectric conversion elements 221.

### <Thermoelectric Conversion Elements 221>

Each of the thermoelectric conversion elements 221 is formed to extend in the direction in which the first electromotive force V1 is generated. Specifically, each of the thermoelectric conversion elements 221 extends in the direction in which the anomalous Nernst effect due to the vertical component Jz is most strongly exhibited. The thermoelectric conversion elements 221 in the present embodiment extend linearly along the direction in which the first electromotive force V1 is generated. The shape of the thermoelectric conversion elements 221 is not limited to this and may, for example, include curved portions. The number of thermoelectric conversion elements 221 included in the thermoelectric conversion device 22 is four in the present embodiment. Note that the number of thermoelectric conversion elements 221 included in one thermoelectric conversion device 22 is not limited to this number and is arbitrary.

### <First Conductor Parts 222 and Second Conductor Parts 223>

The first conductor parts 222 and the second conductor parts 223 are configured to connect the thermoelectric conversion elements 221 in series so as to amplify their respective electromotive forces V1. Regarding the first conductor parts 222 and the second conductor parts 223, each first conductor part 222 is arranged between two thermoelectric conversion elements 221 and extend in approximately the same direction as the direction in which these thermoelectric conversion elements 221 extend.

The second conductor parts 223 extend in a direction perpendicular to the first conductor parts 222, within the plane of the front surface 212 so as to connect the end portions of the thermoelectric conversion elements 221 and the end portions of the first conductor parts 222. Accordingly, each thermoelectric conversion device 22 is configured to include a meander structure in which the thermoelectric conversion elements 221 and the first conductor parts 222 are alternately arranged. Note that the manner of connection of the first and second conductor parts 222 and 223 is arbitrary.

For example, the conductor parts may be arranged to connect the end portions of two adjacent thermoelectric conversion elements 221 in series in a linear manner. In short, the first and second conductor parts 222 and 223 may be configured in any manner as long as they connect the thermoelectric conversion elements 221 included in the thermoelectric conversion device 22 in such a way that the thermoelectromotive force V generated from the thermoelectric conversion elements 221 is reinforced. Note that the first and second conductor parts 222 and 223 can be mounted using any method, such as metal sputtering on the substrate 21 or connecting wires to the end portions of the thermoelectric conversion elements 221.

### <Measurement Terminals 224>

The measurement terminals 224 are configured to enable measurement of the thermoelectromotive force V. Specifically, the measurement terminals 224 are configured to enable measurement of the thermoelectromotive force V output from the thermoelectric conversion elements 221 connected in series by the first and second conductor parts 222 and 223. In the present embodiment, the measurement terminals 224 of the thermoelectric conversion device 22 are electrically isolated from each other. This reduces contact resistance of the thermoelectric conversion device 22 and improves the measurement accuracy of the thermoelectromotive force V. The measurement terminals 224 may be physical connection terminals such as pins, tabs, or ribbon terminals, or may be virtual terminals that serve as measurement points for the thermoelectromotive force V.

Here, the physical properties (specifically, magnetic properties) of the aforementioned thermoelectric conversion elements 221 will be described. Each of the thermoelectric conversion elements 221 is configured to exhibit the anomalous Nernst effect described above.

The thermoelectric conversion elements 221 of the present embodiment include a magnetic material with a magnetic structure capable of exhibiting the anomalous Nernst effect. The magnetic structure may be an antiferromagnetic structure, a canted antiferromagnetic structure, a ferrimagnetic structure, or a ferromagnetic structure, as long as it is capable of exhibiting the anomalous Nernst effect. An antiferromagnetic magnetic order with spontaneous magnetization is also referred to as a weak ferromagnetic structure. The magnetic structure of the magnetic material includes at least one of a first magnetic structure and a second magnetic structure configured to be time-reversal symmetric with respect to the first magnetic structure.

In such a magnetic structure, spontaneous magnetization occurs along the easy magnetization axis. When the magnetic material is a ferromagnet or ferrimagnet, the easy magnetization axis is approximately parallel to the easy spin axis. On the other hand, if the magnetic material is a canted antiferromagnet, the easy magnetization axis extends in a direction different from the easy spin axis (e.g., in the perpendicular direction). In the present embodiment, the thermoelectric conversion elements 221 include a ferrimagnetic material, and its easy magnetization axis lies along the front surface 212. In other words, the easy magnetization axis extends in a direction that is different from the direction in which the thermoelectric conversion elements 221 extend, and that is approximately parallel to the front surface 212.

The thermoelectric conversion elements 221 may be made of any material as long as it includes a substance capable of exhibiting the anomalous Nernst effect. Examples of such compositions that can exhibit the anomalous Nernst effect include Mn₃Sn, Mn₃Ge, Mn₃Ga, Co₂MnGa, Fe₃Al, Fe₃Ga, Fe₂Sn, or alloys, element-substituted materials, or mixtures thereof. The manifestation mechanism of the anomalous Nernst effect is arbitrary, and examples include those caused by antiferromagnetic magnetic structures with non-collinear spin structures. In this case, the Nernst coefficient tends to be larger than that of other manifestation mechanisms, facilitating high-accuracy measurements and miniaturization of the elements.

The thermoelectric conversion elements 221 may be realized either as a polycrystalline body of these materials or as a single crystal body. Note that the crystallographic domain of the single crystal body only needs to be sufficiently uniform to allow observation of asymmetric physical properties resulting from the reduction in symmetry accompanying the emergence of magnetic ordering. The thermoelectric conversion elements 221 of the present embodiment are formed as thin films with a thickness in the direction perpendicular to the front surface 212. The aforementioned easy magnetization axis and easy spin axis tend to extend along the in-plane direction of the front surface 212 due to the magnetic anisotropy resulting from thin-film formation having a greater influence than other factors. This makes it easier to appropriately adjust the direction of the first electromotive force V1 generated by the anomalous Nernst effect.

The thickness of the thermoelectric conversion elements 221 is arbitrary; specifically, it may be, for example, 5, 6, 7, 8, 9, 10, 20, 30, 40, 50, 60, 70, 80, 90, 100, 200, 300, 400, 500, 600, 700, 800, or 900 nm, or it may be within the range between any two of the values illustrated here. Note that it may be outside these ranges.

Additionally, the method for mounting the thermoelectric conversion elements 221 onto the substrate 21 is arbitrary, and any method may be employed, including physical vapor deposition such as sputtering or ion plating, plating, chemical vapor deposition, molecular beam epitaxy (MBE), sintering of powders of the above compound, various printing methods such as inkjet printing using droplets of a solution in which the above compound is dissolved, or three-dimensional printing using the above compound. The method for mounting the thermoelectric conversion elements 221 may be the same as the method for mounting the first and second conductor parts 222 and 223. This makes it possible to simplify the manufacturing process. The thermoelectric conversion elements 221 included in in one thermoelectric conversion device 22 may contain the same magnetic material or different magnetic materials.

In the thermoelectric conversion device 22, as described above, the thermoelectric conversion elements 221 and the first and second conductor parts 222 and 223 form a circuit C1 connecting one measurement terminal 224 to the other measurement terminal 224. The circuit C1 is a circuit that is not in a closed state, which is namely an open circuit. The circuit C1 is connected to the measurement unit 23, which will be described below.

### <Measurement Unit 23>

The measurement unit 23 is configured to measure the heat flux and temperature of the measurement object OB1. The measurement unit 23 is connected to the circuit C1 and forms a circuit C2, which partly includes the circuit C1, and a circuit C3, which also partly includes the circuit C1. The measurement unit 23 has a heat flux measurement unit 24 forming the circuit C2 and a temperature measurement unit 25 forming the circuit C3.

### <Heat Flux Measurement Unit 24>

The heat flux measurement unit 24 is configured to measure the heat flux occurring at the location of the thermoelectric conversion device 22 on the measurement object OB1. The heat flux measurement unit 24 includes a heat flux signal measurement component 241.

### <Heat Flux Signal Measurement Component 241>

The heat flux signal measurement component 241 is connected to the measurement terminals 224 via wiring and forms a portion of the circuit C2. The heat flux signal measurement component 241 measures a value (e.g., voltage or current) related to the electrical signal represented by the current flowing through the circuit C2 due to the thermoelectromotive force V generated by the thermoelectric conversion elements 221. The heat flux signal measurement component 241 is configured, for example, to be able to measure the thermoelectromotive force V that produces the electrical signal.

The heat flux signal measurement component 241 may include, for example, a voltmeter capable of measuring the thermoelectromotive force V. Note that the heat flux signal measurement component 241 is not limited to a voltmeter and may be implemented using various measurement instruments such as an ammeter or LCR meter. Since the current flowing due to the thermoelectromotive force V is minute, the heat flux signal measurement component 241 may include an amplifier that amplifies the electrical signal represented by the minute current. Additionally, the heat flux signal measurement component 241 may include a passive element or an analog-to-digital converter as needed.

The heat flux signal measurement component 241 calculates the heat flux based on the measured thermoelectromotive force V and outputs the calculated heat flux value as a measurement result. The heat flux signal measurement component 241 has a communication function and is connected to the user terminal 4 via wiring. The heat flux signal measurement component 241 outputs (i.e., transmits) the measurement result and other information to the user terminal 4. The heat flux signal measurement component 241 repeatedly performs heat flux measurement and output of the measurement result, for example, at predetermined time intervals.

### <Temperature Measurement Unit 25>

The temperature measurement unit 25 is configured to measure the internal temperature of the thermoelectric conversion device 22 (heat flux sensor), as described above. Since the thermoelectric conversion device 22 is extremely thin, the internal temperature of the thermoelectric conversion device 22 is close to the surface temperature at the measurement point P1 on the measurement object OB1, and can be regarded as the temperature at the measurement point P1 on the measurement object OB1.

The temperature measurement unit 25 includes a temperature signal measurement component 251, a switching component 253, and a control component 254. The temperature signal measurement component 251 is connected to the circuit C2 via wiring and forms a portion of the circuit C3, which includes the circuit C1 and a portion of the circuit C2. The circuit C2, which includes the heat flux signal measurement component 241, and the circuit C3, which includes the temperature signal measurement component 251, both include the circuit C1 and form a parallel circuit.

### <Temperature Signal Measurement Component 251>

The temperature signal measurement component 251 includes a power supply component 252 and, based on a current (hereinafter referred to as a “sensing current”) supplied by the power supply component 252 to the circuit C3, measures a value related to the electrical signal represented by the sensing current flowing through the circuit C3. The temperature signal measurement component 251 measures the electrical resistance of the circuit C3 using a method (e.g., the four-terminal method) capable of measuring extremely small resistance. The main electrical resistance in the circuit C3 is the electrical resistance due to the thermoelectric conversion elements 221. Note that the temperature signal measurement component 251 may measure electrical resistance using other methods, as long as they are capable of measuring extremely small resistance. Additionally, the temperature signal measurement component 251 may include a passive element, an amplifier, or an analog-to-digital converter as needed.

### <Switching Component 253>

The switching component 253 is provided in a path forming the circuit C2 that does not overlap with the circuit C3, and switches between an ON state in which current flows and an OFF state in which no current flows. The term “current” as used herein includes both the current flowing due to the thermoelectromotive force V and the sensing current supplied by the temperature signal measurement component 251. That is, when the switching component 253 is in the ON state, the sensing current supplied by the temperature signal measurement component 251 may flow not only through the circuit C3 but also through the circuit C2. Therefore, by turning off the switching component 253, the sensing current is prevented from flowing into the circuit C2. The switching component 253 is controlled on and off by the control component 254 described below.

### <Control Component 254>

The control component 254 includes a processor, memory, and other components, and controls the operation of each component of the temperature measurement unit 25. The control component 254 is electrically connected to the temperature signal measurement component 251 and the switching component 253, and sends control signals to control their operation. Note that it is assumed that the control signals supplied by the control component 254 do not flow through the circuits C2 and C3. The control component 254, for example, controls the switching component 253 so that no current flows through the circuit C2, and controls the temperature signal measurement component 251 to supply the sensing current to the circuit C3. Then, the control component 254 causes the temperature signal measurement component 251 to measure the electrical resistance of the circuit C3 (i.e., the electrical resistance of the thermoelectric conversion elements 221) and obtains the measurement result.

The control component 254 calculates the internal temperature of the thermoelectric conversion device 22 based on the obtained electrical resistance value. The control component 254 stores, for example, an equation representing the relationship between electrical resistance and temperature, as illustrated in FIGS. 2A and 2B, and calculates the value of temperature corresponding to the measured electrical resistance value. The control component 254 outputs the calculated internal temperature value as the measurement result. The control component 254 is connected to, for example, the user terminal 4 via wiring, and outputs the measurement result to the user terminal 4. The control component 254 repeatedly performs internal temperature measurement and output of the measurement result, for example, at predetermined time intervals.

Note that either or both of the calculation of temperature and output of the measurement result may be performed by the temperature signal measurement component 251. Furthermore, the temperature signal measurement component 251 and the control component 254 may be integrated to collectively perform the operations previously performed by each unit.

The control component 254 may also be connected to the heat flux signal measurement component 241 via wiring and may control the heat flux measurement operations performed by the heat flux signal measurement component 241 as well. For example, when the temperature signal measurement component 251 is supplying a sensing current for temperature measurement, the control component 254 turns off the switching component 253 to prevent the heat flux signal measurement component 241 from measuring heat flux. When the heat flux signal measurement component 241 is measuring heat flux, the control component 254 turns on the switching component 253 to prevent the temperature signal measurement component 251 from supplying a sensing current or measuring temperature.

When heat flux and temperature are measured at the same time, the sensing current supplied by the temperature signal measurement component 251 may flow through the circuit C2 as well, and this sensing current causes the thermoelectric conversion elements 221 to generate heat, making it difficult to conduct accurate heat flux measurements. By performing control to separate the timing of heat flux and temperature measurements as described above, it becomes possible to avoid inaccurate heat flux measurements compared to cases where heat flux and temperature are measured simultaneously.

Note that the method of controlling the temperature signal measurement component 251 and the heat flux signal measurement component 241 is not limited to the above. The control component 254 may, for example, perform control so that the time of temperature measurement by the temperature signal measurement component 251 is staggered from the time of heat flux measurement by the heat flux signal measurement component 241. In this case, the switching component 253 may be maintained in the ON state, or the switching component 253 may be omitted. Additionally, the control component 254 may also perform control such that the interval between heat flux measurements by the heat flux signal measurement component 241 is shorter than the interval between temperature measurements by the temperature signal measurement component 251. In this case, even if some overlap occurs between temperature and heat flux measurements, there will always be timing points at which only heat flux is measured. The user terminal 4 may, for example, employ only the measurement results obtained at timing points at which only heat flux is measured, thereby being able to execute information processing based on the accurate heat flux measurement results.

As described above, the measuring device 2 includes the thermoelectric conversion device 22, the heat flux measurement unit 24, and the temperature measurement unit 25. The thermoelectric conversion device 22 is an example of a thermoelectric conversion circuit that converts heat into electric power. The thermoelectric conversion device 22 includes the thermoelectric conversion elements 221 configured to generate a thermoelectromotive force V due to the temperature gradient J1 caused by heat exchange with the measurement object OB1. The heat flux measurement unit 24 is configured to measure the heat flux occurring at the measurement point P1 on the measurement object OB1, based on the electrical signal generated in the thermoelectric conversion device 22 by the thermoelectromotive force V.

Additionally, the temperature measurement unit 25 applies a second current along a path through which a first current flows due to the thermoelectromotive force V in at least a portion of the thermoelectric conversion device 22, and measures the electrical resistance of at least a portion of the thermoelectric conversion device 22. The path as used herein refers to the current path formed by the circuit C1. Additionally, the first current is the current flowing through the circuit C1 due to the thermoelectromotive force V. The second current is the sensing current supplied to the circuit C1 from the power supply component 252 of the temperature signal measurement component 251.

The temperature measurement unit 25 then measures the electrical resistance of the thermoelectric conversion elements 221 connected in series in the circuit C1 as illustrated in FIG. 5. The temperature measurement unit 25 is configured to measure the temperature of the measurement object OB1 based on the measured electrical resistance. The temperature measurement unit 25, for example, measures the temperature value based on the measured electrical resistance value and the equation representing the relationship between electrical resistance and temperature, which is illustrated in FIGS. 2A and 2B. The measured temperature as above is close to the surface temperature at the measurement point P1 on the measurement object OB1, i.e., the location where the thermoelectric conversion device 22 is provided. Thus, the temperature measured by the temperature measurement unit 25 can be regarded as the temperature of the measurement object OB1.

In the examples of FIG. 4 and other figures, the sensing current is applied across the entire circuit C1 formed by the thermoelectric conversion device 22 to measure the total electrical resistance of the thermoelectric conversion device 22, but the example is not limited to this. The sensing current may instead be applied to only a measurement object path, which is a portion of the circuit C1, and the electrical resistance of this measurement object path may be measured. Note that it is assumed that the measurement object path includes at least one thermoelectric conversion element 221. In that case, an equation expressing the relationship between electrical resistance and temperature in the measurement object path may be determined in advance through experiments or the like, and the temperature measurement unit 25 may then measure the temperature based on that equation.

Additionally, while the example of FIG. 4 and other figures illustrates that the heat flux measurement unit 24 and the temperature measurement unit 25 are separate units, these may be integrated into a single measurement unit. In that case, passive components, amplifiers, and analog-to-digital converters included in the heat flux signal measurement component 241 and the temperature signal measurement component 251 can be shared. Additionally, the switching component 253 may be configured to be included in one or both of the heat flux signal measurement component 241 and the temperature signal measurement component 251. Moreover, these measurement units may be configured to be controlled by an ASIC, FPGA, CPU, or similar components. While FIG. 4 and other figures illustrate a system that detects the output voltage and resistance of the heat flux sensor (thermoelectric conversion device 22), as long as these values can be measurable, heat flow (heat flux) and temperature can be measured. Therefore, other measurement systems may also be employed.

According to the configuration as such, heat flux and temperature can be measured at the same point. In the above-described example, according to the measurement system 1, heat flux and temperature at the measurement point P1 on the measurement object OB1 can be measured simply by providing the single thermoelectric conversion device 22. Moreover, the thermoelectric conversion elements 221 are configured to generate a thermoelectromotive force V based on the anomalous Nernst effect. According to the configuration as such, responsiveness can be enhanced compared to, for example, using a pyroelectric sensor to measure heat flux.

### <User Terminal 4>

The user terminal 4 is configured to execute various types of information processing described below based on the measurement results obtained by a measuring device 2. Details of the user terminal 4 will be described below along with the information processing.

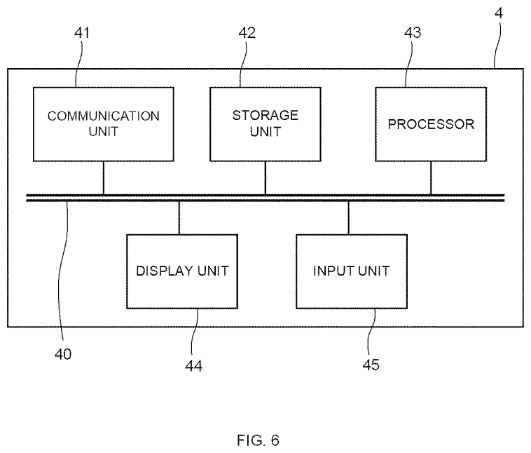

FIG. 6 is a block diagram illustrating the hardware configuration of the user terminal 4. The user terminal 4 includes a communication bus 40, a communication unit 41, a storage unit 42, a processor 43, a display unit 44, and an input unit 45. These components are electrically connected via the communication bus 40 inside the user terminal 4.

### <Communication Unit 41>

It is preferable for the communication unit 41 to include wired communication means such as USB, IEEE 1394, Thunderbolt (registered trademark), and wired LAN network communication. It may also include wireless LAN network communication, mobile communication such as 3G/LTE/5G, and BLUETOOTH (registered trademark) communication as needed. That is, it is more preferable to implement the communication unit 41 as a set of these multiple types of communication means. In other words, the user terminal 4 may communicate various types of information from the outside via the communication unit 41 and the network.

### <Storage Unit 42>

The storage unit 42 stores various types of information as defined by the foregoing description. For example, this may be implemented as a storage device such as a solid-state drive (SSD) that stores various programs pertaining to the user terminal 4, which are executed by the processor 43, or as a memory such as random-access memory (RAM) that stores temporarily required information (such as arguments and arrays) pertaining to the program operations. The storage unit 42 stores various programs, variables, and other related data pertaining to the user terminal 4, which are executed by the processor 43.

### <Processor 43>

The processor 43 processes and controls the overall operation related to the user terminal 4. The processor 43 is, for example, a central processing unit (CPU), which is not illustrated. The processor 43 realizes various functions pertaining to the user terminal 4 by reading a predetermined program stored in the storage unit 42. That is, information processing performed by software stored in the storage unit 42 may be specifically realized by the processor 43, which is an example of hardware, allowing it to be executed as each functional part included in the processor 43. These will be described in more detail in the following section. Note that the processor 43 is not limited to a single unit, and may be implemented with multiple processors 43 for the individual functions. A combination of the above is also acceptable.

### <Display Unit 44>

The display unit 44 may be included in the housing of the user terminal 4, or it may be externally attached. The display unit 44 displays a graphical user interface (GUI) screen that can be operated by the user. For example, it is preferable to implement this by selectively using display devices such as a CRT display, a liquid crystal display, an organic EL display, and a plasma display according to the type of the user terminal 4.

### <Input Unit 45>

The input unit 45 may be included in the housing of the user terminal 4, or it may be externally attached. For example, the input unit 45 may be implemented as a touchscreen integrated with the display unit 44. If it is a touchscreen, the user can input operations such as tapping, swiping, and the like. Of course, instead of a touchscreen, devices such as switch buttons, a mouse, and a QWERTY keyboard may be employed. That is, the input unit 45 receives operation inputs made by the user. These inputs are transferred as command signals to the processor 43 via the communication bus 40, and the processor 43 may execute predetermined control or calculations as needed.

The measurement system 1, which includes the above-described user terminal 4, is an information processing system that includes the measuring device 2 and at least one processor (processor 43). This processor is configured to execute processing based on the temperature of the measurement object measured by the temperature measurement unit 25 and the heat flux measured using the heat flux measurement unit 24.

Processing based on temperature and heat flux includes, for example, processing to measure the temperature deep inside the measurement object OB1. Moreover, processing based on temperature and heat flux additionally includes information processing such as material analysis if the measurement object is a material, behavior control of a processing device if the measurement object is a processed workpiece, or behavior control of a drive device if the measurement object is the drive device. According to the configuration as such, information processing with higher accuracy can be performed compared to cases where information processing is performed based on heat flux and temperature measured at different points on the measurement object.

### <Modification: Sensing Current in Two Directions>

A modification of the present embodiment will now be described.

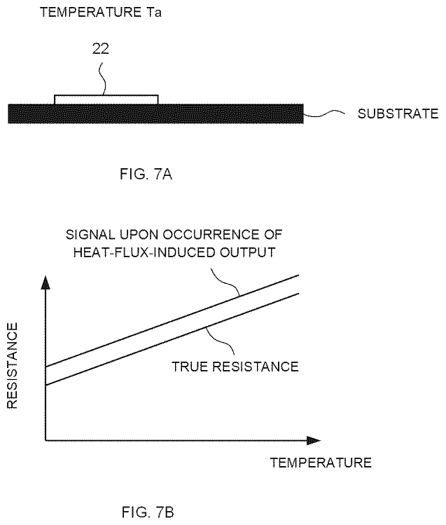

FIGS. 7A and 7B include diagrams illustrating an example of measurement errors. As illustrated in FIGS. 7A and 7B, when measuring the resistance of the heat flux sensor (thermoelectric conversion device 22), a voltage caused by the heat flux is output as the heat flux passes through, which may result in superimposed resistance errors.

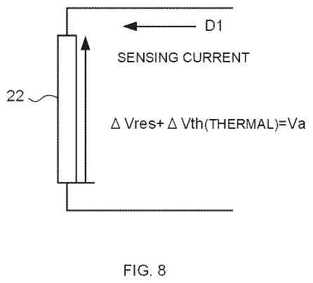

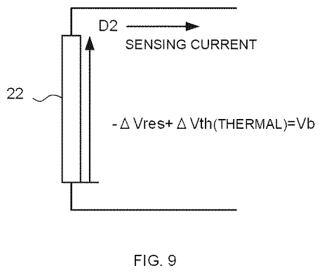

FIGS. 8 and 9 are diagrams illustrating an example of a measuring method. As illustrated in FIGS. 8 and 9, by reversing the polarity and measuring the resistance, the output voltage induced by the heat flux can be canceled. Specifically, by reversing the direction of the sensing current used to measure the resistance of the heat flux sensor (thermoelectric conversion device 22), as in a first direction D1 illustrated in FIG. 8 and a second direction D2 illustrated in FIG. 9, the respective outputs become:

$$\begin{matrix}Δ Vres + Δ Vth ( thermal ) = Va … in the case of the first direction D 1 \\ - Δ Vres + Δ Vth ( thermal ) = Vb … in the case of the second direction D 2\end{matrix}$$

### Therefore,

$$Va - Vb = Δ Vres + Δ Vth - ( - Δ Vres + Δ Vth ) = 2 Δ Vres$$

and the true resistance can be obtained.

As described above, the temperature measurement unit 25 is configured to measure the electrical resistance of the thermoelectric conversion device 22 based on the difference between the measured voltage value when the second current (sensing current) is applied in the first direction D1 and the measured voltage value when the second current (sensing current) is applied in the second direction D2, which is opposite to the first direction D1. According to the configuration as such, it becomes possible to eliminate the resistance errors described above and improve the accuracy of temperature measurement compared to cases where electrical resistance is measured only based on a sensing current flowing in only one direction of the path.

<Modification: Sensing Current with Periodicity>

Another modification of the present embodiment will now be described.

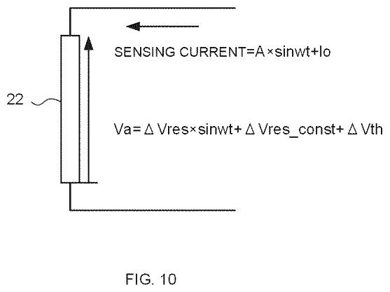

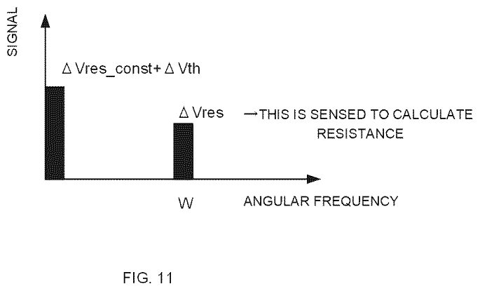

FIGS. 10 and 11 are diagrams illustrating an example of a sensing current. In the example illustrated in FIG. 10, the sensing current used to measure the resistance has periodicity. This allows the heat-flux-induced signal and the resistance-induced signal to be separated in the frequency domain. For example, when frequency analysis is performed, as illustrated in FIG. 11:

$$Va = Δ Vres \times sin ω t + Δ Vres\_const + Δ Vth$$

By extracting the component of angular frequency @, the resistance can be obtained.

In such a frequency analysis, methods such as FFT (Fast Fourier Transformation), lock-in amplifier, or heterodyne may be used as appropriate. For example, in the case of analysis using a lock-in amplifier (which multiplies a frequency-driven signal by a signal of the same frequency), the following expression is obtained:

$$Va = ( Δ Vres \times sin ω t + Δ Vres\_const + Δ Vth ) \times sin ω t = A \times sin ω t + B \times sin 2 ω t + 0.5 \times Δ Vres$$

(where A and B are constants)

In this case, by performing signal processing such as applying a low-pass filter that can remove the components A×sinωt+B×sin2ωt from the above signal, 0.5×ΔVres can be extracted.

As described above, the temperature measurement unit 25 is configured to separate a first voltage value based on the thermoelectromotive force V and a second voltage value induced by the resistance of the element (thermoelectric conversion elements 221) from the measured voltage value when a periodic current is applied as the second current (sensing current) to at least a portion of the thermoelectric conversion circuit (thermoelectric conversion device 22), and to measure the electrical resistance based on the second voltage value. The “ΔVres_const+ΔVth” indicated in FIG. 11 is an example of the first voltage value, and “ΔVres” indicated in FIG. 11 is an example of the second voltage value. According to the configuration as such, the effects of voltage fluctuations due to heat flux during temperature measurement can be removed, thereby improving temperature measurement accuracy compared to cases where voltage value separation is not performed.

### <Modification: Correction of Resistance-Temperature Relationship>

If there is a non-linear relationship between the resistance of the thermoelectric conversion circuit (or resistance of the measurement object path) and temperature, correction may be performed using methods such as linear correction, lookup tables (information associating resistance to temperature, or information associating these to other parameters), or machine learning models.

In that case, the temperature measurement unit 25 is configured to measure the temperature of the measurement object based on the electrical resistance, measured by applying a sensing current, and the correction information. The correction information refers to information used to correct the relationship between the measured electrical resistance and the temperature of the measurement object. Examples of the correction information include correction programs for linear correction, lookup tables that associate resistance and temperature, or machine learning models generated by training artificial intelligence on such relationships. By using such correction information, the temperature measurement unit 25 corrects a non-linear relationship between resistance and temperature to a linear relationship and measures the temperature based on the resistance. According to the configuration as such, the accuracy of temperature measurement can be improved compared to cases where correction information is not used.

### <Modification: Surface Temperature>

As another modification, the following configuration is provided in order to create a stable thermal space.

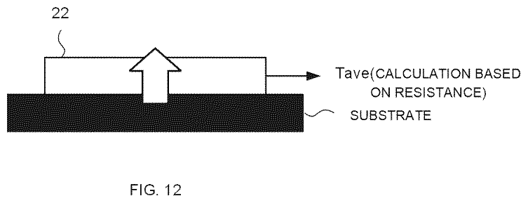

FIG. 12 is a diagram for describing the temperature being measured. As illustrated in FIG. 12, the temperature derived from the resistance of the heat flux sensor (thermoelectric conversion device 22) can be estimated as the average temperature of the heat flux sensor as it is based on the resistance of the heat flux sensor. Since the electrical signal obtained from the heat flux sensor reveals the heat flux (i.e., the temperature gradient ΔT), the temperatures at the top side and bottom side of the heat flux sensor can also be estimated. Specifically, since the heat flux sensor output=sensitivity×ΔT (temperature difference between top and bottom), ΔT=heat flux sensor output/sensitivity.

Then, if the bottom side is hotter than the top side,

$$\begin{matrix}T ( top side ) = Tave ( average temperature of heat flux sensor ) - Δ T / 2 \\ T ( bottom side ) = Tave + Δ T / 2 ,\end{matrix}$$

and if the top side is hotter than the bottom side,

$$\begin{matrix}T ( top side ) = Tave ( average temperature ) + Δ T / 2 \\ T ( bottom side ) = Tave - Δ T / 2\end{matrix}$$

As described above, the measuring device 2 further includes a temperature difference measurement unit configured to measure the temperature difference between a first surface (a surface on the contact surface 211 side) of the element (thermoelectric conversion elements 221), which faces the measurement object, and a second surface (a surface on the front surface 212 side) on the opposite side, based on the voltage generated in the thermoelectric conversion circuit (thermoelectric conversion device 22) by the thermoelectromotive force V. The temperature difference measurement unit may be provided separately from the heat flux measurement unit 24 and the temperature measurement unit 25, or either the heat flux measurement unit 24 or the temperature measurement unit 25 may also serve as the temperature difference measurement unit.

The measuring device 2 is also configured to measure the temperature of the first surface (contact surface 211) or the second surface (front surface 212) based on the measured temperature and the measured temperature difference. Note that the measuring device 2 may measure the temperature of both the first and second surfaces. The temperature of the surfaces of these thermoelectric conversion elements 221 may be measured by the heat flux measurement unit 24 or the temperature measurement unit 25, or by a temperature difference measurement unit provided separately from these units. Since the thermoelectric conversion elements 221 themselves are very thin elements, even the internal temperature of the thermoelectric conversion elements 221 can be regarded as the temperature at the measurement point P1 on the measurement object OB1, as described above. However, by using the aforementioned temperature difference, even more accurate temperatures can be measured.

### <Information Processing>

Information processing executed by the measurement system 1 will now be described.

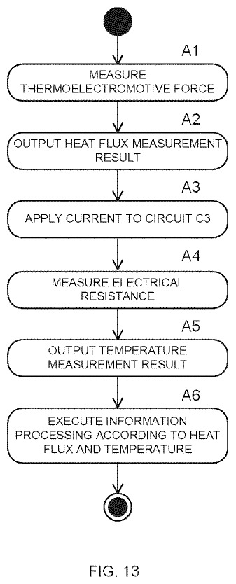

FIG. 13 is an activity diagram illustrating an example of the flow of information processing. Note that the information processing may include arbitrary exceptional processing, which is not illustrated in the figure. The exceptional processing includes interruption of the information processing or omission of certain processes. The selection or input performed in the information processing may be based on a user operation or may be performed automatically without depending on any user operation.

First, the measuring device 2 measures the thermoelectromotive force V generated in the thermoelectric conversion device 22 based on an electrical signal represented by the current flowing through the circuit C2 due to the thermoelectromotive force V (activity A1). The measuring device 2 repeatedly measures the thermoelectromotive force V, for example, at predetermined time intervals. Next, the measuring device 20 calculates the value of the heat flux occurring in the thermoelectric conversion device 22 based on the measured thermoelectromotive force V, and outputs the calculated value as the heat flux measurement result (activity A2). The measuring device 2 outputs the heat flux measurement result to, for example, the user terminal 4.

Next, the measuring device 2 applies a current to the circuit C3, which includes the thermoelectric conversion device 22 (activity A3). The measuring device 2 applies a current to the circuit C3 at a timing point at which the heat flux measurement is not performed. Next, the measuring device 2 measures the electrical resistance of the thermoelectric conversion device 22 based on the electrical signal represented by the current flowing through the circuit C3 (activity A4). The measuring device 2 then calculates the value of the temperature of the measurement object based on the measured electrical resistance, and outputs the calculated value as the temperature measurement result (activity A5). The measuring device 2 outputs the temperature measurement result to, for example, the user terminal 4.

The user terminal 4 then performs information processing according to the heat flux and temperature of the measurement object based on the heat flux and temperature measurement results that have been output (activity A6). Note that the heat flux measurement processing in activities A1 and A2 and the temperature measurement processing in activities A3, A4, and A5 may be performed in reverse order, or they may be performed at different measurement frequencies. In addition, activity A6 may be executed at a frequency different from that of the heat flux and temperature measurements.

The measuring method illustrated by the activity diagram of FIG. 13 is configured such that the measurement system 1 is able to perform a heat flux measurement step (activities A1 and A2), a current control step (activity A3), a resistance measurement step (activity A4), and a temperature measurement step (activity A5). In the heat flux measurement step, the measurement system 1 measures the heat flux occurring in the measurement object OB1 based on an electrical signal generated by the thermoelectromotive force V in the thermoelectric conversion device 22 (an example of a thermoelectric conversion circuit) including the thermoelectric conversion elements 221 (an example of an element) configured to generate the thermoelectromotive force V due to the temperature gradient J1 caused by heat exchange with the measurement object OB1

Additionally, in the current control step, the measurement system 1 controls the power supply component 252 to supply the second current (sensing current) along a path through which the first current flows due to the thermoelectromotive force V in at least a portion of the thermoelectric conversion device 22. In the resistance measurement step, the measurement system 1 measures the electrical resistance of at least a portion of the thermoelectric conversion device 22 using the second current. In the temperature measurement step, the measurement system 1 measures the temperature of the measurement object OB1 based on the measured electrical resistance. This enables measurement of both the heat flux and temperature of the measurement object undergoing heat exchange with the thermoelectric conversion circuit, such as the thermoelectric conversion device 22. Accordingly, a single thermoelectric conversion circuit can measure heat flux and temperature at the same point on the measurement object.

### Other Modifications

The embodiment of the measurement system 1 described above is merely an example and is not limited thereto. For example, the measuring device 2 and the user terminal 4 have been described as separate devices, but they may be integrated. Additionally, the information processing performed by the user terminal 4 may be performed by the measuring device 2, or the information processing (such as heat flux calculation or temperature calculation) performed by the measuring device 2 may be performed by the user terminal 4. Moreover, the measuring device 2 and the user terminal 4 may be configured to enable wireless communication.

The calculations (such as heat flux calculation or temperature calculation) performed by the measurement system 1 are not limited to those using digital signals; they may also be performed using analog circuits, such as adder circuits, or a combination thereof. Moreover, the components (e.g., the thermoelectric conversion device 22, heat flux measurement unit 24, and temperature measurement unit 25) included in the measuring device 2 may be arranged on the same substrate.

The information processing performed by an external device of the measuring device 2 (such as the user terminal 4) may be implemented in an on-premise configuration or a cloud-based configuration. As an example of a cloud-based external device, the aforementioned functions and processing may be provided in the form of a cloud-based configuration using a Saas (Software as a Service) model or through cloud computing. Furthermore, various types of storage and control performed by the measuring device 2 and the user terminal 4 may be assigned to multiple external devices. In other words, various types of information and programs may be stored in a distributed manner across multiple external devices using blockchain technology or the like.

The above-described embodiment is not limited to the measurement system 1, and may instead be an information processing method or an information processing program. The information processing method includes the steps of the measurement system 1. The information processing program causes at least one computer to execute the steps of the measurement system 1.

The measurement system 1 and other configurations described above may be provided in each of the following modes.
(1) A measuring device, comprising: a thermoelectric conversion circuit; a heat flux measurement unit; and a temperature measurement unit, wherein the thermoelectric conversion circuit includes an element configured to generate an electromotive force due to a temperature gradient caused by heat exchange with a measurement object, the heat flux measurement unit is configured to measure a heat flux occurring in the measurement object, based on an electrical signal generated in the thermoelectric conversion circuit by the electromotive force, and the temperature measurement unit is configured to apply a second current along a path through which a first current flows due to the electromotive force in at least a portion of the thermoelectric conversion circuit, measure an electrical resistance of at least a portion of the thermoelectric conversion circuit, and measure a temperature of the measurement object based on the electrical resistance.

According to the configuration as such, heat flux and temperature can be measured at the same point.
(2) The measuring device according to (1), wherein: the element is configured to generate the electromotive force based on an anomalous Nernst effect.

According to the configuration as such, responsiveness can be enhanced.
(3) The measuring device according to (1) or (2), wherein: the temperature measurement unit is configured to measure the electrical resistance based on a difference between a measured voltage value when the second current is applied in a first direction of the path and a measured voltage value when the second current is applied in a second direction opposite to the first direction.

According to the configuration as such, the accuracy of temperature measurement can be enhanced.
(4) The measuring device according to any one of (1) to (3), wherein: the temperature measurement unit is configured to separate a first voltage value based on the electromotive force and a second voltage value induced by a resistance of the element from a measured voltage value when a current having periodicity is applied as the second current in at least a portion of the thermoelectric conversion circuit, and measure the electrical resistance based on the first voltage value.

According to the configuration as such, the accuracy of temperature measurement can be enhanced.
(5) The measuring device according to any one of (1) to (4), wherein: the temperature measurement unit is configured to measure the temperature of the measurement object based on correction information, which is for correcting a relationship between the measured electrical resistance and the temperature of the measurement object, and the electrical resistance.

According to the configuration as such, the accuracy of temperature measurement can be enhanced.
(6) The measuring device according to any one of (1) to (5), further comprising: a temperature difference measurement unit configured to measure a temperature difference between a first surface of the element facing the measurement object and a second surface on an opposite side, based on a voltage generated in the thermoelectric conversion circuit by the electromotive force, wherein a temperature of the first surface or the second surface is measured based on the measured temperature and the measured temperature difference.

According to the configuration as such, the temperature can be measured with higher accuracy.
(7) An information processing system comprising: the measuring device according to any one of (1) to (6); and at least one processor, wherein the at least one processor is configured to execute processing based on a temperature of the measurement object measured by the temperature measurement unit and a heat flux measured using the heat flux measurement unit.

According to the configuration as such, heat flux and temperature can be measured at the same point.
(8) A measuring method comprising: a heat flux measurement step of measuring, in a thermoelectric conversion circuit including an element configured to generate an electromotive force due to a temperature gradient caused by heat exchange with a measurement object, a heat flux occurring in the measurement object, based on an electrical signal generated by the electromotive force; a current control step of controlling a power supply to supply a second current along a path through which a first current flows due to the electromotive force in at least a portion of the thermoelectric conversion circuit; a resistance measurement step of measuring an electrical resistance of at least a portion of the thermoelectric conversion circuit using the second current; and a temperature measurement step of measuring a temperature of the measurement object based on the measured electrical resistance.

According to the configuration as such, heat flux and temperature can be measured at the same point.

Of course, the above are not the only possible implementations.

Finally, although various embodiments of the present disclosure have been described, these are presented merely as examples and are not intended to limit the scope of the invention. The novel embodiments may be implemented in various other forms, and various omissions, substitutions, and changes can be made without departing from the gist of the invention. Such embodiments and their modifications are included within the scope and gist of the invention, and also within the scope of the invention as defined in the claims and their equivalents.

1. A measurement apparatus, comprising:
a thermoelectric conversion circuit;
a heat flux measurement unit; and
a temperature measurement unit,
wherein the thermoelectric conversion circuit includes an element configured to generate an electromotive force due to a temperature gradient caused by heat exchange with a measurement object,
the heat flux measurement unit implemented by circuitry is configured to measure a heat flux occurring in the measurement object, based on an electrical signal generated in the thermoelectric conversion circuit by the electromotive force, and
the temperature measurement unit implemented by circuitry is configured to apply a second current along a path through which a first current flows due to the electromotive force in at least a portion of the thermoelectric conversion circuit, measure an electrical resistance of at least a portion of the thermoelectric conversion circuit, and measure a temperature of the measurement object based on the electrical resistance.

2. The measurement apparatus according to claim 1, wherein:
the element is configured to generate the electromotive force based on an anomalous Nernst effect.

3. The measurement apparatus according to claim 1, wherein:
the temperature measurement unit is configured to measure the electrical resistance based on a difference between a measured voltage value when the second current is applied in a first direction of the path and a measured voltage value when the second current is applied in a second direction opposite to the first direction.

4. The measurement apparatus according to claim 1, wherein:
the temperature measurement unit is configured to separate a first voltage value based on the electromotive force and a second voltage value induced by a resistance of the element from a measured voltage value when a current having periodicity is applied as the second current in at least a portion of the thermoelectric conversion circuit, and measure the electrical resistance based on the second voltage value.

5. The measurement apparatus according to claim 1, wherein:
the temperature measurement unit is configured to measure the temperature of the measurement object based on correction information, which is for correcting a relationship between the measured electrical resistance and the temperature of the measurement object, and the electrical resistance.

6. The measurement apparatus according to claim 1, further comprising:
a temperature difference measurement unit implemented by circuitry configured to measure a temperature difference between a first surface of the element facing the measurement object and a second surface on an opposite side, based on a voltage generated in the thermoelectric conversion circuit by the electromotive force,
wherein a temperature of the first surface or the second surface is measured based on the measured temperature and the measured temperature difference.

7. An information processing system comprising:
the measurement apparatus according to claim 1; and
at least one processor,
wherein the at least one processor is configured to execute
processing based on a temperature of the measurement object measured by the temperature measurement unit and a heat flux measured using the heat flux measurement unit.

8. A measuring method comprising:
a heat flux measurement step of measuring, in a thermoelectric conversion circuit including an element configured to generate an electromotive force due to a temperature gradient caused by heat exchange with a measurement object, a heat flux occurring in the measurement object, based on an electrical signal generated by the electromotive force;
a current control step of controlling a power supply to supply a second current along a path through which a first current flows due to the electromotive force in at least a portion of the thermoelectric conversion circuit;
a resistance measurement step of measuring an electrical resistance of at least a portion of the thermoelectric conversion circuit using the second current; and
a temperature measurement step of measuring a temperature of the measurement object based on the measured electrical resistance.
